(19) United States
(12) Patent Application Publication
(10) Pub. No.: US 2010/0246213 A1
(43) Pub. Date: Sep. 30, 2010

(54) LIGHT EMITTING DEVICE, DISPLAY DEVICE AND MANUFACTURING METHOD OF THE LIGHT EMITTING DEVICE

(75) Inventor: Shuichi Naijo, Chiba-shi (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Minato-ku, Tokyo (JP)

(21) Appl. No.: 12/679,104

(22) PCT Filed: Sep. 17, 2008
(86) PCT No.: PCT/JP2008/066721

§ 371 Date: Mar. 19, 2010

(30) Foreign Application Priority Data
Sep. 21, 2007 (JP) 2007-245731

(51) Int. Cl. F21V 7/04; H01L 33/48; H01L 33/64

(52) U.S. Cl. 362/613; 257/89; 438/28; 257/E33.056; 257/E33.075

(57) ABSTRACT

A light emitting module (40) includes: eight LEDs emitting red, green and blue light; electric conductor part (60) electrically connected to the LEDs and constitute power feeding routes for the LEDs; a heat conductor part (50) provided so as to be electrically insulated from the electric conductor parts (60) and constitute a heat dissipating route for heat produced by the LEDs; and a lens (70) which seals the LEDs while including respective parts of the electric conductor parts (60) and the heat conductor part (50). Bending process is applied to each of the electrodes, such as a red positive lead electrode portion (61a), of the electric conductor part (60) which are exposed from the lens (70) and a heat dissipating portion (52) etc. in the heat conductor part (50) which are exposed from the lens (70). Accordingly, temperature change in the light emitting elements and accompanying light intensity change are suppressed, and at the same time, thinning of the light emitting device including the light emitting elements is achieved.

### TECHNICAL FIELD

The present invention relates to a light emitting device, a display device and a manufacturing method of the light emitting device, using light emitting elements.

### BACKGROUND ART

Recently, display devices such as liquid crystal display devices, typified by, for example, a liquid crystal display television and a liquid crystal display monitor, have adopted a backlight device as a light source for emitting light from the back, side or the like of a display panel. Examples of the backlight device include what is called an edge light (side-light) type in which a light source is disposed on two or one side of a light guide plate made of a transparent resin so that light incident on the light guide plate is reflected by a reflector disposed on the back surface of the light guide plate, thus illuminating the surface of a liquid crystal display panel.

A fluorescent tube such as a hot-cathode fluorescent tube or a cold-cathode fluorescent tube is generally used in such a backlight device. On the other hand, technologies of backlight device using light emitting diodes (LED), which are a type of light emitting elements, as their light source, have been recently developed as a substitute for such backlight devices using the fluorescent tubes.

As a backlight device with a side-light type, which uses the light emitting diodes, a backlight device is known in which a light source formed of plural light emitting diodes mounted on a substrate is disposed on one side of a light guide plate (for example, refer to Patent Document 1).

Patent Document 1: Japanese Patent Application Laid Open Publication No. 6-3527

### DISCLOSURE OF THE INVENTION

### Problems to be Solved by the Invention

The light emitting elements such as LEDs produce heat at the time of light emission. In addition, it is known that the light emission efficiency of the light emitting elements such as LEDs is changed in accordance with the temperature change. Thus, a countermeasure for suppressing temperature change of a light source is required.

Further, such a display device is required to be thinner and lighter. In response to this requirement, the light source is necessary to reduce the thickness in a direction perpendicular to a surface of a display panel of the backlight system.

An object of the present invention is to suppress the temperature change of the light emitting elements and light intensity change thereof associated with the temperature change, and to make a thinner light emitting device including the light emitting elements.

### Means for Solving the Problems

In order to attain the above-mentioned object, there is provided a light emitting device to which the present invention is applied including: a plurality of light emitting elements; an electric conductor that is electrically connected to each of the plurality of light emitting elements, and that forms a power feeding route for the plurality of light emitting elements; a heat conductor that is disposed so as to be electrically insulated from the electric conductor, and that forms a heat dissipating route for heat produced by the plurality of light emitting elements; and a sealing part that seals the plurality of light emitting elements while including a part of the electric conductor and a part of the heat conductor. Respective portions, exposed from the sealing part, of the electric conductor and the heat conductor are bent.

In such a light emitting device, the sealing part has a passage surface through which light emitted from the plurality of light emitting elements passes, and the heat conductor is bent toward the passage surface side of the sealing part. Further, the plurality of light emitting elements are arrayed in line. Furthermore, the plurality of light emitting elements includes a red light emitting element that emits red light, a green light emitting element that emits green light, and a blue light emitting element that emits blue light, and the electric conductor has a red power feeding route for feeding electric power to the red light emitting element, a green power feeding route for feeding electric power to the green light emitting element, and a blue power feeding route for feeding electric power to the blue light emitting element. Still furthermore, the electric conductor includes a plurality of electrodes that receive power feeding from an outside, and a connecting conductor that electrically connects each of the plurality of electrodes and the plurality of light emitting elements, the heat conductor includes a holding part that holds the plurality of light emitting elements, and a transmission part that is connected to the holding part and that transmits heat produced by the plurality of light emitting elements through the holding part, and respective parts of the electrodes are exposed from the sealing part in the electric conductor, and a part of the transmission part is exposed from the sealing part in the heat conductor. In this case, the plurality of electrodes forming the electric conductor are arranged side by side on one end portion side of the sealing part, and the transmission part forming the heat conductor is arranged on the other end portion side of the sealing part.

From another aspect of the present invention, there is provided a display device including: a display panel for displaying an image; and a backlight that is disposed on a back side of the display panel and that illuminates, with light, the display panel from the back side thereof. The backlight includes: a light guide plate that emits light incident on a side surface thereof toward the display panel; and a light source that illuminates, with light, the light guide plate from the side surface thereof. The light source includes: a plurality of light emitting elements; an electric conductor that is electrically connected to each of the plurality of light emitting elements, and that forms a power feeding route for the plurality of light emitting elements; a heat conductor that is disposed so as to be electrically insulated from the electric conductor, and that forms a heat dissipating route for heat produced by the plurality of light emitting elements; and a sealing part that seals the plurality of light emitting elements while including a part of the electric conductor and a part of the heat conductor. Respective portions, exposed from the sealing part, of the electric conductor and the heat conductor are bent.

In such a display device, a plurality of the light sources are attached so as to be arrayed side by side along the side surface of the light guide plate. In this case, the display device further includes a wiring board that is arranged so as to stride the plurality of light sources, and electrically connected to the electric conductor disposed in each of the plurality of light sources. Further, the heat conductor is bent in a direction closer to the light guide plate, and the electric conductor is bent in a direction away from the light guide plate. Furthermore, the sealing part has a passage surface through which light emitted from the plurality of light emitting elements passes, the passage surface being aspheric.

From further aspect of the present invention, there is provided a manufacturing method of a light emitting device including a plurality of light emitting elements, an electric conductor that is electrically connected to each of the plurality of light emitting elements and forms a power feeding route for the plurality of light emitting elements, a heat conductor that is disposed so as to be electrically insulated from the electric conductor and forms a heat dissipating route for heat produced by the plurality of light emitting elements, and a sealing part that seals the plurality of light emitting elements. The manufacturing method includes the steps of: mounting the plurality of light emitting elements on a lead frame in which the electric conductor and the heat conductor are connected through a bridging part; forming the sealing part to the lead frame having the plurality of light emitting elements mounted thereon, the sealing part sealing the plurality of light emitting elements while including a part of the electric conductor and a part of the heat conductor; removing the bridging part from the lead frame having the sealing part formed thereto; and bending respective portions, exposed to an outside, of the electric conductor and the heat conductor.

In such a manufacturing method of the light emitting device, the electric conductor of the lead frame includes a plurality of electrodes that receive power feeding from an outside, and a connecting conductor that electrically connects the plurality of electrodes and the plurality of light emitting elements, the heat conductor of the lead frame includes a holding part that holds the plurality of light emitting elements, and a transmission part that is connected to the holding part and that transmits heat produced by the plurality of light emitting elements through the holding part, and the step of forming includes exposing respective parts of the electrodes from the sealing part, and exposing a part of the transmission part from the sealing part. Further, in the step of forming, the sealing part is not formed to the bridging part. Furthermore, the step of forming includes forming, to the sealing part, a passage surface through which light emitted from the plurality of light emitting elements having been sealed passes. In this case, the step of bending includes bending the heat conductor toward the passage surface side of the sealing part, and bending the electric conductor toward a side opposite to the passage surface side.

### ADVANTAGES OF THE INVENTION

According to the present invention, it is possible to suppress the temperature change of the light emitting elements and light intensity change thereof associated with the temperature change, and to make a thinner light emitting device including the light emitting elements.

### BEST MODES FOR CARRYING OUT THE INVENTION

Hereinafter, an exemplary embodiment of the present invention will be described in detail with reference to the accompanying drawings.

FIG. 1 is a view showing an entire configuration of a liquid crystal display device to which the exemplary embodiment is applied. The liquid crystal display device includes a liquid crystal display module 20, and a backlight device 10 disposed on a back side of the liquid crystal display module 20 (a lower side in FIG. 1). Incidentally, the backlight device 10 with a so-called side-light type is used in the present exemplary embodiment.

The backlight device 10 includes a light source device 11, a light guide plate 12, a reflecting sheet 13, a diffusing sheet 14, prism sheets 15 and 16, and a brightness improvement film 17.

The light source device 11 is arranged so as to face one side (namely, the long side) of the light guide plate 12. In the present exemplary embodiment, the light source device 11 is configured of an array of plural LEDs that each emit any of red (R), green (G) and blue (B) light. Incidentally, the configuration of the light source device 11 will be described in detail later.

The light guide plate 12 has a rectangular shape corresponding to a liquid crystal panel 21, and is made of, for example, an acrylic resin with excellent light transmission properties. Reflecting dots formed of concavities and convexities, white ink or the like (neither of which is shown in the figure) are formed on a surface of the light guide plate 12 facing the liquid crystal display module 20.

The reflecting sheet 13 is arranged in close contact with the surface of the light guide plate 12 opposite to the surface thereof having the dots formed thereon. The reflecting sheet 13 is formed of a film of a white color or a metallic luster.

The diffusing sheet 14 is arranged in close contact with the surface of the light guide plate 12 opposite to the surface facing the reflecting sheet 13. The diffusing sheet 14 is a film made of a laminate of optical films, for example.

The prism sheets 15 and 16 are disposed on the diffusing sheet 14 (or on the side thereof close to the liquid crystal display module 20). The prism sheets 15 and 16 are formed of diffraction grating films orthogonal to each other.

The brightness improvement film 17 is arranged in contact with the upper surface of the prism sheet 16 to protect the prism sheet 16. The brightness improvement film 17 is made of, for example, a laminate of optical films, similarly to the diffusing sheet 14.

On the other hand, the liquid crystal display module 20 includes the liquid crystal panel 21 as a display panel composed of two glass substrates with liquid crystal in between, and polarization plates 22 and 23 for restricting the oscillation of optical wave to a given direction. Here, each of the polarization plates 22 and 23 is stacked on each glass substrate of the liquid crystal panel 21. Further, to the liquid crystal display module 20, peripheral members such as an LSI for driving (not shown in the figure) are equipped.

The liquid crystal panel 21 includes various structural components not shown in the figure. For example, the two glass substrates have display electrodes, active elements such as a thin film transistor (TFT: thin film transistor), liquid crystal, a spacer, sealant, an orientation film, a common electrode, a protective film, a color filter, and the like which are not shown in the figure.

Incidentally, the structural unit of the backlight system 10 may be selected in an arbitrary way. For example, the unit including only the light source device 11 and the light guide plate 12 may be called as a “backlight device (backlight)” and distributed as a service unit not including the reflecting sheet 13, the diffusing sheet 14, the prism sheets 15 and 16, the brightness improvement film 17 and the like.

A description will be given with regard to operation of the backlight device 10.

When the red (R), green (G) and blue (B) LEDs of the light source device 11 are turned on, beams of red (R), green (G) and blue (B) light emitted from the LEDs are incident on the light guide plate 12 from one side thereof. Then, the light guide plate 12 guides the light led from the light source device 11 into the light guide plate 12 throughout the entire area of the light guide plate 12, using total reflection by a material (e.g., the acrylic resin) of the light guide plate 12. The guided light is reflected by the reflecting sheet 13, and is emitted to the surface of the light guide plate 12. At this time, the light guided by the reflecting dots formed on the surface of the light guide plate 12 changes its course, and the light is guided to the reflecting sheet 13, again. By repeating this, the light is uniformly emitted from the entire surface of the light guide plate 12. Meanwhile, the beams of red (R), green (G) and blue (B) light are mixed to form white light, which is then emitted.

The light emitted from the surface of the light guide plate 12 in this manner is scattered and diffused at the diffusing sheet 14 and is emitted in more uniform manner. Then, the light emitted from the diffusing sheet 14 is focused forward, or equivalently, toward the brightness improvement film 17 (or the liquid crystal display module 20), at the prism sheets 15 and 16. Then, the light emitted from the prism sheet 16 is further scattered and diffused by the brightness improvement film 17, and is emitted to the liquid crystal display module 20. Therefore, the liquid crystal display module 20 receives an entry of light that is whitened by sufficient color mixture, is uniform in intensity throughout the entire surface, and is improved in brightness throughout the entire surface.

FIG. 2A is a perspective view of the light source device 11 used in the backlight device 10 shown in FIG. 1, and FIG. 2B is a perspective view of the light source device 11, which is disassembled into principal structural components.

The light source device 11 includes a light emitting unit 31 having the group of LEDs (not shown in the figure), a wiring board 32 that feeds electric power to the group of LEDs of the light emitting unit 31, and a heat dissipating plate 33 that escapes heat produced in accordance with the light emission of the group of LEDs of the light emitting unit 31. Incidentally, the group of LEDs that constitutes the light emitting unit 31 includes plural red LEDs, plural green LEDs, and plural blue LEDs, as will be described later.

Among them, the light emitting unit 31 has an array of ten light emitting modules 40 (specifically, 40a to 40j) arrayed in line. The wiring board 32 is formed of, for example, a flexible printed board (FPC: Flexible Printed Circuits) having a rectangular shape, and is mounted on the upper side, in the figure, of the ten light emitting modules 40a to 40j forming the light emitting unit 31 so as to straddle the ten light emitting modules 40a to 40j. On the other hand, the heat dissipating plate 33 is made of a metallic plate having, for example, a rectangular shape, and is mounted on the lower side, in the figure, of the ten light emitting modules 40a to 40j forming the light emitting unit 31 so as to straddle the ten light emitting modules 40a to 40j.

FIG. 3A is a perspective view of one of the light emitting modules 40 forming the light emitting unit 31 shown in FIGS. 2A and 2B, and FIG. 3B is a cross-sectional view of FIG. 3A taken along a line IIIB-IIIB. Incidentally, all of the light emitting modules 40a to 40j have the same configuration. Moreover, each light emitting module 40 incorporates plural red LEDs, plural green LEDs and plural blue LEDs, as described later.

The light emitting module 40 as a light emitting device incorporates wirings while sealing plural LEDs including a second red LED R2 shown in FIG. 3B, and includes a lens 70 having a lens surface 70a for emitting, in a desired direction, light received from each LED, a red positive lead electrode portion 61a and a red negative lead electrode portion 61b for feeding electric power to the plural red LEDs including the second red LED R2, a green positive lead electrode portion 62a and a green negative lead electrode portion 62b for feeding electric power to the plural green LEDs, a blue positive lead electrode portion 63a and a blue negative lead electrode portion 63b for feeding electric power to plural blue LEDs, and a heat dissipating portion 52 that dissipates heat produced by each LED to the outside.

Here, plural electrodes, that is, the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b, are arranged side by side along a longitudinal direction of the lens 70 in a state of being exposed on the upper side, in the figure, of the lens 70. These electrodes are arrayed in the following order from the left side of the figure: the green positive lead electrode portion 62a, the red positive lead electrode portion 61a, the blue positive lead electrode portion 63a, the red negative lead electrode portion 61b, the green negative lead electrode portion 62b and the blue negative lead electrode portion 63b. The red positive lead electrode portion 61a and the red negative lead electrode portion 61b, the green positive lead electrode portion 62a and the green negative lead electrode portion 62b, and the blue positive lead electrode portion 63a and the blue negative lead electrode portion 63b are serially connected to the plural red LEDs, the plural green LEDs and the plural blue LEDs incorporated in the lens 70, respectively.

The heat dissipating portion 52 has a rectangular shape, and is disposed in a state of being exposed on the lower side, in the figure, of the lens 70. In this heat dissipating portion 52, three opening holes 52c are formed along the longitudinal direction of the lens 70. Further, the heat dissipating portion 52 is thermally connected to the plural red LEDs, the plural green LEDs and the plural blue LEDs incorporated in the lens 70.

Here, the red positive lead electrode portion 61a, the red negative lead electrode portion 61b, the green positive lead electrode portion 62a, the green negative lead electrode portion 62b, the blue positive lead electrode portion 63a, the blue negative lead electrode portion 63b and the heat dissipating portion 52 are made of a metallic plate (for example, a copper plate) having the same thickness (for example, 0.15 mm). In addition, the red positive lead electrode portion 61a, the red negative lead electrode portion 61b, the green positive lead electrode portion 62a, the green negative lead electrode portion 62b, the blue positive lead electrode portion 63a, the blue negative lead electrode portion 63b and the heat dissipating portion 52 are formed in the same plane, in the lens 70.

The lens 70 functioning as a sealing part has a cross section formed into a bullet shape, and the lens surface 70a functioning as a passage surface is aspheric. Further, the lens 70 is made of a resin material transparent in the visible region, such as a silicone resin. Furthermore, the lens 70 incorporates the plural LEDs including the second red LED R2, and one end portion side of each of the red positive lead electrode portion 61a, the red negative lead electrode portion 61b, the green positive lead electrode portion 62a, the green negative lead electrode portion 62b, the blue positive lead electrode portion 63a, the blue negative lead electrode portion 63b and the heat dissipating portion 52.

Here, the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b are bent toward a side opposite to the lens surface 70a of the lens 70, and the respective end portions of these electrodes are bent toward the back side of the lens 70. On the other hand, the heat dissipating portion 52 is bent toward the lens surface 70a of the lens 70, and the free end thereof projects farther than the lens surface 70a. In other words, the bending direction of the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b and the bending direction of the heat dissipating portion 52 are opposite to each other.

Incidentally, the wiring board 32 shown in FIGS. 2A and 2B is soldered to the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b disposed in each light emitting module 40, as shown with broken lines in FIG. 3B. On the other hand, the heat dissipating plate 33 shown in FIGS. 2A and 2B is placed on the heat dissipating portion 52 disposed in each light emitting module 40, as shown in FIG. 3B. Here, both of the wiring board 32 and the heat dissipating plate 33 are arranged so as to project toward the lens surface 70a of the lens 70. White resist layers 32a and 33a are formed on one side of the wiring board 32 facing the lens 70 and one side of the heat dissipating plate 33 facing the lens 70, respectively. These white resist layers 32a and 33a function as reflectors that reflect, to the right side in FIG. 3B, that is, toward the light guide plate 12 shown in FIG. 1, the light emitted from each LED toward the upper side and the lower side in FIG. 3B through the lens surface 70a of the lens 70.

FIG. 4 is a development view for explaining an internal configuration of the light emitting module 40. Incidentally, FIG. 4 corresponds to a top view of the light emitting module 40 in a state before the red positive lead electrode portion 61a, the red negative lead electrode portion 61b, the green positive lead electrode portion 62a, the green negative lead electrode portion 62b, the blue positive lead electrode portion 63a, the blue negative lead electrode portion 63b and the heat dissipating portion 52 are bent.

The light emitting module 40 includes a heat conductor part 50 including the heat dissipating portion 52, an electric conductor part 60 including the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b, and the lens 70. Further, the light emitting module 40 includes plural (eight) LEDs functioning as light emitting elements, that is, a first red LED R1, the second red LED R2, a first green LED G1, a second green LED G2, a third green LED G3, a fourth green LED G4, a first blue LED B1 and a second blue LED B2. Here, the first red LED R1 and the second red LED R2, the first green LED G1, the second green LED G2, the third green LED G3 and the fourth green LED G4, and the first blue LED B1 and the second blue LED B2 function as red light emitting elements, green light emitting elements and blue light emitting elements, respectively.

The heat conductor part 50 has a holding portion 51 extending along the longitudinal direction of the lens 70, at a central portion of the lens 70 in a lateral direction. At both ends of the holding portion 51 in the longitudinal direction, a first connecting portion 53 and a second connecting portion 54 are disposed, respectively. The first connecting portion 53 and the second connecting portion 54 are used for connecting the holding portion 51 to the heat dissipating portion 52. Thereby, predetermined space is formed among the holding portion 51, the heat dissipating portion 52, the first connecting portion 53 and the second connecting portion 54. Incidentally, the holding portion 51, the heat dissipating portion 52, the first connecting portion 53 and the second connecting portion 54 are integrally formed by one metallic plate.

To the holding portion 51, the first green LED G1, the first red LED R1, the second green LED G2, the first blue LED B1, the third green LED G3, the second red LED R2, the fourth green LED G4 and the second blue LED B2 are attached in this order from the left side of the figure, and are held by the holding portion 51. In other words, in this example, the green LEDs are alternately arranged, and any of the red LED or blue LED is arranged therebetween. Here, three LEDs are arranged between the red LEDs, and between the blue LEDs. Here, the LEDs adjacent to each other are set to have the same interval. In the present exemplary embodiment, the dimension of the lens 70 is set in advance so that, for example, in a case of arraying the two light emitting modules 40 in line, an interval between the second blue LED B2 disposed on the one end portion side of one light emitting module 40 (right side in the figure) and the first green LED G1 disposed on the other end portion side of the other light emitting module 40 (left side in the figure) is equal to the interval between the LEDs adjacent to each other in the same light emitting module 40. Incidentally, each LED is attached to the holding portion 51 in an electrically insulated state. A heat dissipating route from the holding portion 51 having the LEDs mounted thereon to the heat dissipating portion 52 through the first connecting portion 53 and the second connecting portion 54 is formed in the heat conductor part 50.

The holding portion 51 includes a first projection portion 51a extending toward a side opposite to the heat dissipating portion 52 from an attachment portion of the second green LED G2, and a second projection portion 51b extending toward the side opposite to the heat dissipating portion 52 from an attachment portion of the third green LED G3. These first and second projection portions 51a and 51b extend to one end portion of the lens 70 in the lateral direction.

On the other hand, the heat dissipating portion 52, functioning as a transmission part, includes a third projection portion 52a and a fourth projection portion 52b formed therein, in the space formed by the above-mentioned holding portion 51, heat dissipating portion 52, first connecting portion 53 and second connecting portion 54. The third projection portion 52a and the fourth projection portion 52b extend toward the holding portion 51. The third projection portion 52a and the fourth projection portion 52b extend to the inside of the lens 70.

The electric conductor part 60 includes: a red electric conductor part 61 including a red connecting conductor 61c in addition to the red positive lead electrode portion 61a and the red negative lead electrode portion 61b; a green electric conductor part 62 including a first green connecting conductor 62c, a second green connecting conductor 62d and a third green connecting conductor 62e in addition to the green positive lead electrode portion 62a and the green negative lead electrode portion 62b; and a blue electric conductor part 63 including a blue connecting conductor 63c in addition to the blue positive lead electrode portion 63a and the blue negative lead electrode portion 63b. Here, the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b each have a cross shape, and each have a wider portion arranged so as to straddle a boundary portion with the lens 70.

The red connecting conductor 61c forming the red electric conductor part 61 is arranged in the space formed by the holding portion 51, the heat dissipating portion 52, the first connecting portion 53 and the second connecting portion 54. Moreover, the red connecting conductor 61c is disposed so as to pass by the first red LED R1 and the second red LED R2.

The first green connecting conductor 62c forming the green electric conductor part 62 is arranged so as to enclose the red positive lead electrode portion 61a in the lens 70. Further, the first green connecting conductor 62c is disposed so as to pass by the first green LED G1 and the second green LED G2. The second green connecting conductor 62d forming the green electric conductor part 62 is arranged so as to enclose the blue positive lead electrode portion 63a in the lens 70. Further, the second green connecting conductor 62d is disposed so as to pass by the second green LED G2 and the third green LED G3. The third green connecting conductor 62e forming the green electric conductor part 62 is arranged so as to enclose the red negative lead electrode portion 61b in the lens 70. Further, the third green connecting conductor 62e is disposed so as to pass by the third green LED G3 and the fourth green LED G4.

The blue connecting conductor 63c forming the blue electric conductor part 63 is arranged in the space formed by the holding portion 51, the heat dissipating portion 52, the first connecting portion 53 and the second connecting portion 54, similarly to the red connecting conductor 61c. Further, the blue connecting conductor 63c is disposed so as to pass by the first blue LED B1 and the second blue LED B2.

Each of the red positive lead electrode portion 61a and the anode terminal of the first red LED R1, the cathode terminal of the first red LED R1 and the red connecting conductor 61c, the red connecting conductor 61c and the anode terminal of the second red LED R2, and the cathode terminal of the second red LED R2 and the red negative lead electrode portion 61b are electrically connected to each other by use of a bonding wire. Thereby, a red power feeding route from the red positive lead electrode portion 61a to the red negative lead electrode portion 61b through the bonding wires, that is, the red electric conductor part 61 is formed.

Further, each of the green positive lead electrode portion 62a and the anode terminal of the first green LED G1, the cathode terminal of the first green LED G1 and the first green connecting conductor 62c, the first green connecting conductor 62c and the anode terminal of the second green LED G2, the cathode terminal of the second green LED G2 and the second green connecting conductor 62d, the second green connecting conductor 62d and the anode terminal of the third green LED G3, the cathode terminal of the third green LED G3 and the third green connecting conductor 62e, the third green connecting conductor 62e and the anode terminal of the fourth green LED G4, and the cathode terminal of the fourth green LED G4 and the green negative lead electrode portion 62b are electrically connected to each other by use of a bonding wire. Thereby, a green power feeding route from the green positive lead electrode portion 62a to the green negative lead electrode portion 62b through the bonding wires, that is, the green electric conductor part 62 is formed.

Furthermore, each of the blue positive lead electrode portion 63a and the anode terminal of the first blue LED B1, the cathode terminal of the first blue LED B1 and the blue connecting conductor 63c, the blue connecting conductor 63c and the anode terminal of the second blue LED B2, and the cathode terminal of the second blue LED B2 and the blue negative lead electrode portion 63b are electrically connected to each other by use of a bonding wire. Thereby, a blue power feeding route from the blue positive lead electrode portion 63a to the blue negative lead electrode portion 63b through the bonding wires, that is, the blue electric conductor part 63 is formed.

Note that, in this example, the red connecting conductor 61c, the first green connecting conductor 62c, the second green connecting conductor 62d, the third green connecting conductor 62e, the blue connecting conductor 63c and the bonding wires function as a connecting conductor.

All of the structural members forming the red electric conductor part 61, the green electric conductor part 62 and the blue electric conductor part 63, which form the electric conductor part 60, are spaced at predetermined intervals with the structural members of the heat conductor part 50. In the present exemplary embodiment, a transparent resin having insulation properties, which forms the lens 70, is filled in the spaces for the intervals, and thus the heat conductor part 50 and the electric conductor part 60 are electrically insulated from each other. The red power feeding route, the green power feeding route and the blue power feeding route are spaced at predetermined intervals. The transparent resin having insulation properties, which forms the lens 70, is filled also in the spaces for the intervals, and thus the power feeding routes for the respective colors are also electrically insulated from each other. Note that, in the example shown in FIG. 4, the bonding wire for any one of the other colors is arranged so as to stride each of the red connecting conductor 61c, the first green connecting conductor 62c, the second green connecting conductor 62d and the third green connecting conductor 62e. However, these bonding wires are respectively attached so as not to be in contact with the conductors that the bonding wires respectively stride.

FIG. 5 is a view for explaining flows of the electricity and the heat in the light emitting module 40. Note that, in this description, it is assumed that the red drive current IR, the green drive current IG and the blue drive current IB are respectively fed to the red electric conductor part 61, the green electric conductor part 62 and the blue electric conductor part 63. Note that, in FIG. 5, the illustration of the bonding wires are omitted. In addition, in FIG. 5, the flow of the electricity (electric current) and the flow of the heat are respectively indicated by arrows with solid lines and arrows with dashed lines.

The red drive current IR flows in the red positive lead electrode portion 61a, the first red LED R1, the red connecting conductor 61c, the second red LED R2 and the red negative lead electrode portion 61b. Thereby, the first red LED R1 and the second red LED R2 emit red light. Further, the green drive current IG flows in the green positive lead electrode portion 62a, the first green LED G1, the first green connecting conductor 62c, the second green LED G2, the second green connecting conductor 62d, the third green LED G3, the third green connecting conductor 62e, the fourth green LED G4 and the green negative lead electrode portion 62b. Thereby, the first green LED G1, the second green LED G2, the third green LED G3 and the fourth green LED G4 emit green light. Furthermore, the blue drive current IB flows in the blue positive lead electrode portion 63a, the first blue LED B1, the blue connecting conductor 63c, the second blue LED B2 and the blue negative lead electrode portion 63b. Thereby, the first blue LED B1 and the second blue LED B2 emit blue light. Incidentally, light from the LEDs for the RGB colors is emitted to the outside (front side in the figure) through the lens 70.

In response to the light emission of the first red LED R1, the second red LED R2, the first green LED G1, the second green LED G2, the third green LED G3, the fourth green LED G4, the first blue LED B1 and the second blue LED B2, these LEDs produce heat. At this time, the heat produced by these LEDs are transmitted from the holding portion 51 to the heat dissipating portion 52 through the first connecting portion 53 and the second connecting portion 54. Here, the heat dissipating portion 52 is exposed to the outside as shown in FIGS. 3A and 3B, and the heat dissipating plate 33 made of a metal is arranged so as to be in contact with the heat dissipating portion 52, and thus the transmitted heat is dissipated to the air through the heat dissipating portion 52 and the heat dissipating plate 33.

In the present exemplary embodiment, by adopting such a configuration, the heat produced by the LEDs for the respective colors disposed in the lens 70 is difficult to remain in the light emitting module 40, and the rate of the temperature increase in these LEDs for the respective colors slows. In general, the light emission efficiency of an LED is easy to be decreased if the temperature thereof gets higher, and thereby the intensity of the light emission is likely to decrease. In addition, an influence on an LED by the temperature increase depends on a color of the LED, and thus the ratio of the light intensities for RGB colors balanced in the general environment may be broken under the environment at the high temperature. As a result, it is feared that color unevenness may occur. Accordingly, by adopting such a configuration, occurrence of various kinds of failures in response to the temperature change of the LEDs for the respective colors is to be suppressed.

In the present exemplary embodiment, by bending the red positive lead electrode portion 61a, the red negative lead electrode portion 61b, the green positive lead electrode portion 62a, the green negative lead electrode portion 62b, the blue positive lead electrode portion 63a, the blue negative lead electrode portion 63b and the heat dissipating portion 52, increase in the thickness of the light emitting module 40 in the direction orthogonal to the light emission direction is suppressed. Thereby, the thickness of the light source device 11 manufactured by use of the light emitting module 40, and further the thicknesses of the backlight device 10 and the liquid crystal display device are thinner. Here, since the heat dissipating portion 52 is bent toward the lens surface 70a side of the lens 70, the heat dissipating portion 52, the light guide plate 12 and the like can be overlapped with each other. Thus, the increase in the sizes of the backlight device 10 and the liquid crystal display device manufactured by use of the light emitting module 40 is to be suppressed. In addition, by bending the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b, the attachment of the wiring board 32 is facilitated.

In this example, the LEDs are arrayed in line in the light emitting module 40, and the plural light emitting modules 40 are arrayed so as to form the light source device 11. Thus, the increase in the thickness of the light emitting module 40 in the direction orthogonal to the light emission direction is to be suppressed also by this configuration. Moreover, in this example, by forming the light source device 11 by use of the plural light emitting modules 40, yield of the light source device 11 is improved in comparison with a case where the light source device 11 is formed by use of one light emitting module 40 having more LEDs. In addition, in this example, since the power feeding is performed by attaching the wiring board 32 to the plural light emitting modules 40, the configuration is simplified in comparison with a case where the wiring boards 32 are individually attached to the light emitting modules 40, and the cost for the manufacture is also reduced.

Next, a description will be given of a manufacturing method of the above-mentioned light emitting modules 40.

FIG. 6 is a flowchart for explaining a manufacturing process of the light emitting modules 40.

Firstly, a lead frame in which the heat conductor part 50 and the electric conductor part 60 are integrated by a predetermined patterning is prepared, and the LEDs for the respective colors are mounted on this lead frame (step 101). Next, the lens 70 is formed on the lead frame having the LEDs for the respective colors mounted thereon (step 102). Then, specific portions of the lead frame having the lens 70 formed thereon are cut (step 103). Finally, a bending processing is performed on the lead frame after cutting the specific portions (step 104). Thereby, the light emitting module 40 is obtained.

FIG. 7 is a top view of a lead frame 80 that is an initial material in the manufacture of the light emitting module 40. Note that, the lead frame 80 is obtained by punching out a metallic plate made of copper or the like to a desired pattern.

This lead frame 80 includes a base 81 including structural components of the electric conductor part 60 except the red connecting conductor 61c and the blue connecting conductor 63c, in addition to the above-mentioned structural components of the heat conductor part 50 and the electric conductor part 60. Specifically, the base 81 includes the green positive lead electrode portion 62a, the first green connecting conductor 62c, the red positive lead electrode portion 61a, the second green connecting conductor 62d, the blue positive lead electrode portion 63a, the third green connecting conductor 62e, the red negative lead electrode portion 61b, the green negative lead electrode portion 62b and the blue negative lead electrode portion 63b. Note that, in addition to these components, the base 81 includes the first projection portion 51a and the second projection portion 51b, which are disposed in the holding portion 51 forming the heat conductor part 50, attached thereto.

Meanwhile, the heat dissipating portion 52 forming the heat conductor part 50 in this lead frame 80 includes the above-mentioned red connecting conductor 61c and blue connecting conductor 63c forming the electric conductor part 60.

In the lead frame 80, as mentioned above, the heat dissipating portion 52 and the base 81 are integrated through the first connecting portion 53, the second connecting portion 54 and the holding portion 51 (first projection portion 51a and the second projection portion 51b). Accordingly, in the lead frame 80, the structural components of the heat conductor part 50 and the structural components of the electric conductor part 60 are integrated so as not to be separated from each other. Incidentally, in this example, as will be described later, all components of the base 81, respective parts of the first projection portion 51a and the second projection portion 51b in the heat conductor part 50 and respective parts of the red connecting conductor 61c, the first green connecting conductor 62c, the second green connecting conductor 62d, the third green connecting conductor 62e and the blue connecting conductor 63c in the electric conductor part 60 function as a bridging part. Thus, all of or a part of these structural members are cut in the cutting process in step 103.

The base 81 of the lead frame 80 has a rectangular shape, and is arranged so as to face the heat dissipating portion 52 through the holding portion 51. Moreover, the base 81 may include three opening holes 81a formed thereon in the longitudinal direction, similarly to the holding portion 51. Note that, the base 81 and the heat dissipating portion 52 are usable for transportation or positioning of the lead frame 80 in each manufacturing process or timing between the manufacturing processes, together with the opening holes 81a and 52c formed in the corresponding members.

FIG. 8 is a top view of the lead frame 80 having the LEDs mounted thereon in the above-mentioned step 101. Note that, in the mounting process, the lead frame 80 is set on a die bonding device not shown in the figure. Then, the mounting (die bonding) of the LEDs on the holding portion 51 in the lead frame 80 is performed. Thereafter, the lead frame 80 after being subjected to the die bonding is set on a wire bonding device not shown in the figure, and the connections between the electrodes, the connecting conductors and the LEDs in the lead frame 80 are achieved by use of the bonding wires (wire bonding).

FIG. 9 is a top view of the lead frame 80 having the lens 70 formed thereon in the above-mentioned step 102, and FIG. 10 is a cross sectional view of FIG. 9 taken along a line X-X. Incidentally, in a sealing process for forming the lens 70, the lead frame 80 having the LEDs mounted thereon is set in a frame in a molding device not shown in the figure, and a melting resin material is injected into the frame and then cured. After that, the lead frame 80 having the lens 70 formed thereon is detached from the frame.

Here, the lens 70 is formed in a state where a predetermined interval is secured between the heat dissipating portion 52 and the base 81. In addition, the lens 70 seals the LEDs, and is formed so as to stride wider portions of the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b, on the base 81 side, as mentioned above. On the other hand, the lens 70 is formed so as to stride the third projection portion 52a and the fourth projection portion 52b, on the heat dissipating portion 52 side, as mentioned above. Further, the lens 70 has both end portions in the longitudinal direction located at positions corresponding to those of the both end portions of the heat dissipating portion 52 and the base 81 in the longitudinal direction. Furthermore, the lens 70 is formed so as to stride one surface and the other surface of the lead frame 80. Incidentally, the lens surface 70a is formed on the one surface side of these surfaces, that is, on the mounting surface side of LEDs. Thereby, the holding portion 51, for example, forming the heat conductor part 50 is kept in a state where the holding portion 51 is entirely covered by the lens 70. The first projection portion 51a, the second projection portion 51b, the third projection portion 52a, the fourth projection portion 52b, the first connecting portion 53 and the second connecting portion 54, which form the heat conductor part 50, are kept in a state where they are covered by the lens 70 except the respective end portions thereof on any one of the base 81 side and the heat dissipating portion 52 side. On the other hand, in the electric conductor part 60, the red positive lead electrode portion 61a, the red negative lead electrode portion 61b and the red connecting conductor 61c forming the red electric conductor part 61, the green positive lead electrode portion 62a, the green negative lead electrode portion 62b, the first green connecting conductor 62c, the second green connecting conductor 62d and the third green connecting conductor 62e forming the green electric conductor part 62, and the blue positive lead electrode portion 63a, the blue negative lead electrode portion 63b and the blue connecting conductor 63c forming the blue electric conductor part 63 are kept in the state where they are covered by the lens 70 except the respective end portions thereof on any one of the base 81 side and the heat dissipating portion 52 side.

FIG. 11 is a top view of the lead frame 80 after the specific portions are cut in the above-mentioned step 103. Note that, in the cutting process, the lead frame 80 is set on a conductor punching device not shown in the figure, and the punching of the specific portions of the lead frame is performed by use of a predetermined punch die and blade (which are not shown in the figure).

In the cutting process, portions of the lead frame 80, which are shown with dashed lines in FIG. 11, are cut. Specifically, in the cutting process, the base 81 of the lead frame 80, the respective portions of the first green connecting conductor 62c, the second green connecting conductor 62d, the third green connecting conductor 62e, the first projection portion 51a and the second projection portion 51b, which are connected to the base 81 and are not covered by the lens 70, are removed. In the cutting process, the respective portions of the red connecting conductor 61c and the blue connecting conductor 63c, which are connected to the heat dissipating portion 52 and are not covered with the lens 70, are also removed.

Thus, the lead frame 80 after being subjected to the cutting process is completely separated into the heat conductor part 50 and the electric conductor part 60. At this time, in the heat conductor part 50, the holding portion 51 and the heat dissipating portion 52 are connected to each other through the first connecting portion 53 and the second connecting portion 54, so that the heat dissipating route is formed. The red connecting conductor 61c and the blue connecting conductor 63c are independently formed in an internal region of the lens 70 included in the space enclosed by the holding portion 51, the heat dissipating portion 52, the first connecting portion 53 and the second connecting portion 54 of the heat conductor part 50. The red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b are also independently formed in the state where the respective one sides thereof are incorporated in the lens 70 and the respective other sides thereof are exposed to the outside. The first green connecting conductor 62c, the second green connecting conductor 62d and the third green connecting conductor 62e are also independently formed in a state of being incorporated in the lens 70.

Since the structural members of the red electric conductor part 61 and the red LEDs are connected with each other by use of the bonding wires, the red power feeding route is to be formed inside the lens 70. Further, since the structural members of the green electric conductor part 62 and the green LEDs are connected with each other by use of the bonding wires, the green power feeding route is to be formed inside the lens 70. Furthermore, the structural members of the blue electric conductor part 63 and the blue LEDs are connected with each other by use of the bonding wires, the blue power feeding route is to be formed inside the lens 70.

FIG. 12 is a cross-sectional view of the lead frame 80 after being subjected to the bending processing in the above-mentioned step 104, that is, the finished light emitting module 40. Here, FIG. 12 corresponds to a cross section of FIG. 11 taken along a line XII-XII. Incidentally, in the bending process, the lead frame 80 is set in a bending processor not shown in the figure, and the lead frame 80 is bent.

In the bending process, the lead frame 80 is bent along the both end portions of the lens 70 in the longitudinal direction. First, in the heat conductor part 50, the third projection portion 52a and the fourth projection portion 52b of the heat dissipating portion 52, the first connecting portion 53 and the second connecting portion 54 are bent toward the lens surface 70a side of the lens 70. As a result, the heat dissipating portion 52 is positioned on the lens surface 70a side of the lens 70. Here, in the present exemplary embodiment, the third projection portion 52a and the fourth projection portion 52b are disposed in the heat dissipating portion 52 in advance. By this configuration, excessive force is not applied to the first connecting portion 53 and the second connecting portion 54 at the bending processing, and the heat dissipating portion 52 is more easily supported by the lens 70 after the bending.

On the other hand, in the electric conductor part 60, the respective one end portions of the red positive lead electrode portion 61a, the red negative lead electrode portion 61b, the green positive lead electrode portion 62a, the green negative lead electrode portion 62b, the blue positive lead electrode portion 63a and the blue negative lead electrode portion 63b, which are held by the lens 70, are bent toward a side opposite to the lens surface 70a of the lens 70, and then the other free end portions thereof are bent toward the back side of the lens 70. The one end sides held by the lens 70, which are firstly bent, are wider than the other portions, as shown in FIG. 11, for example. Thus, the force applied on the portions to be bent is dispersed, and thereby each electrode is difficult to be cut at the bending.

Incidentally, through the bending processing, for example, it is difficult to bring the lens 70 and the heat dissipating portion 52 after the bending into close contact with each other, in consideration of the demand on the processing accuracy. Thus, a narrow gap exists between the lens 70 and the heat dissipating portion 52 after the bending processing. In the present exemplary embodiment, it has been expected that such a gap would be formed through the bending processing. Thus, the heat dissipating plate 33 shown in FIG. 2 is inserted into the gap between the lens 70 and the heat dissipating portion 52 (see FIG. 3B).

### BRIEF DESCRIPTION OF THE DRAWINGS

FIG. 1 is a view showing an entire configuration of a liquid crystal display device to which the exemplary embodiment is applied;

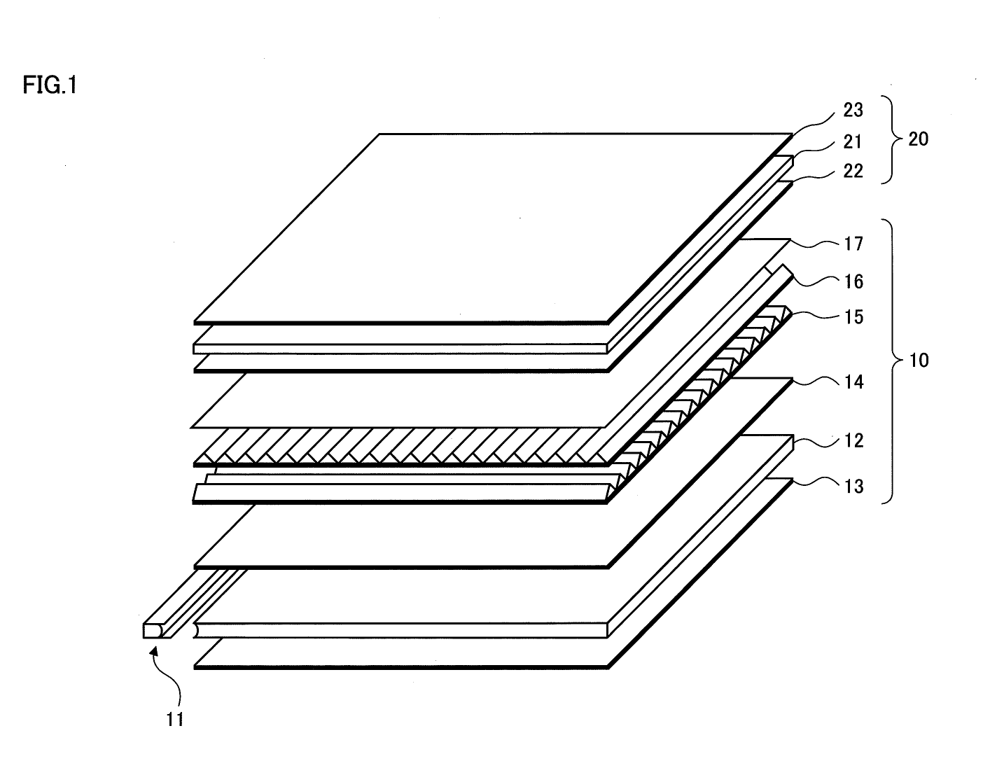

FIG. 2A is a perspective view of the light source device, and FIG. 2B is a perspective view of the light source device, which is disassembled into principal structural components;

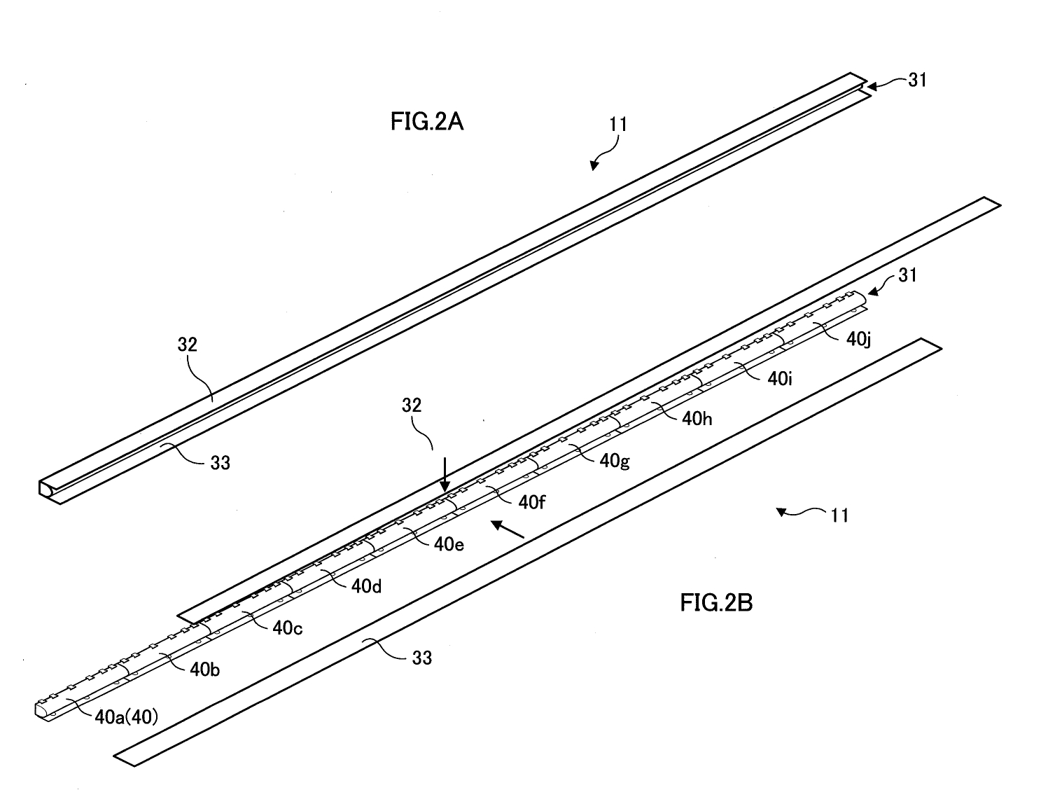

FIG. 3A is a perspective view of one of the light emitting modules, and FIG. 3B is a cross-sectional view of FIG. 3A taken along a line IIIB-IIIB;

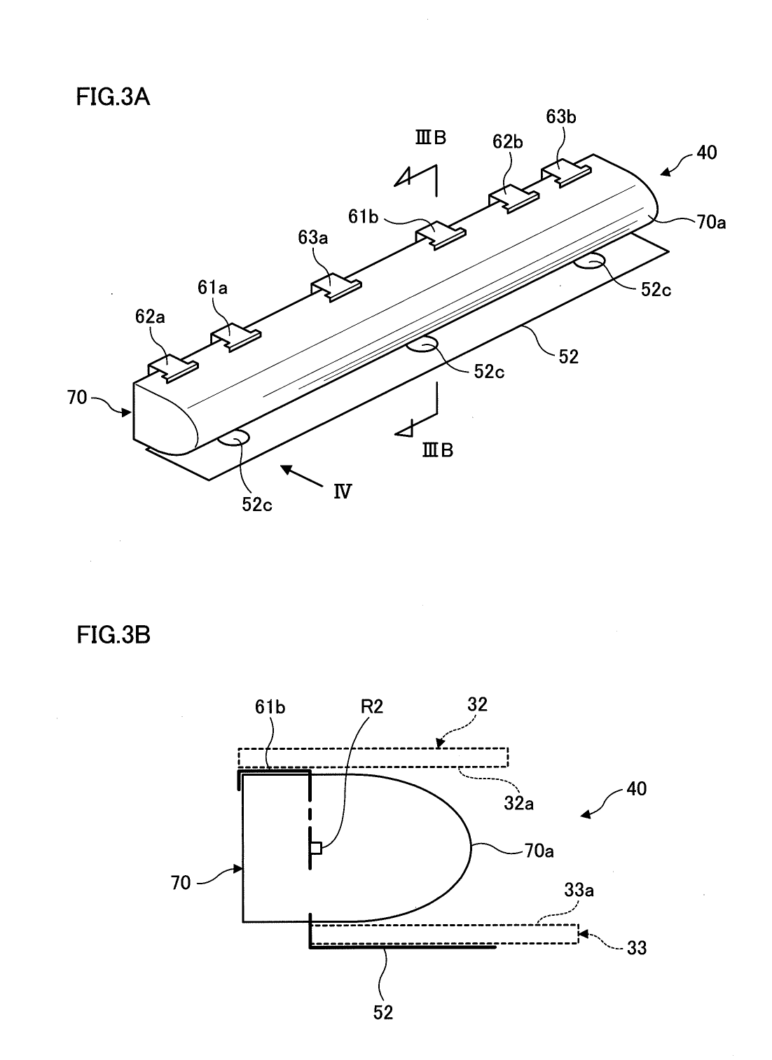

FIG. 4 is a development view for explaining an internal configuration of the light emitting module;

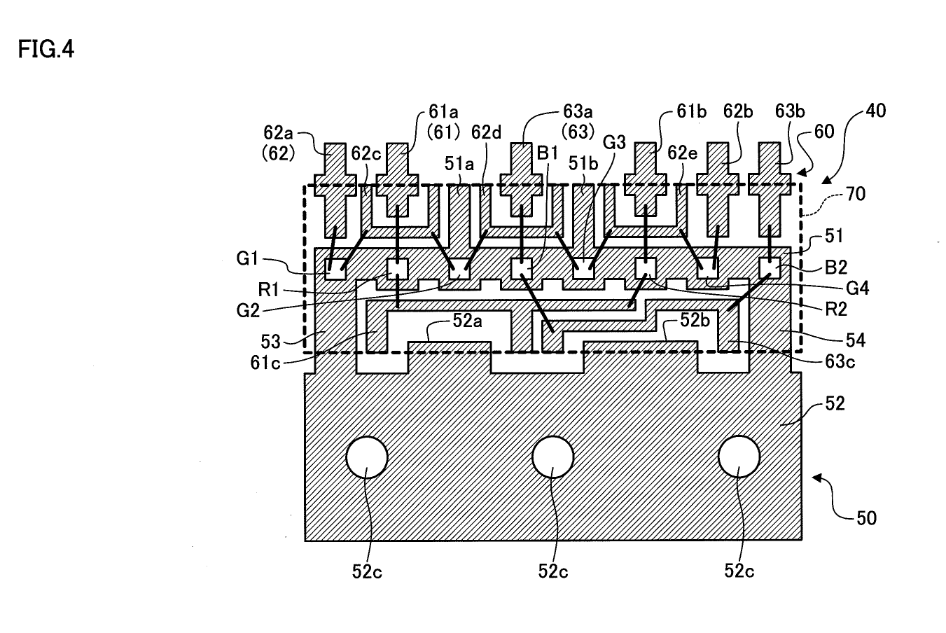

FIG. 5 is a view for explaining flows of the electricity and the heat in the light emitting module;

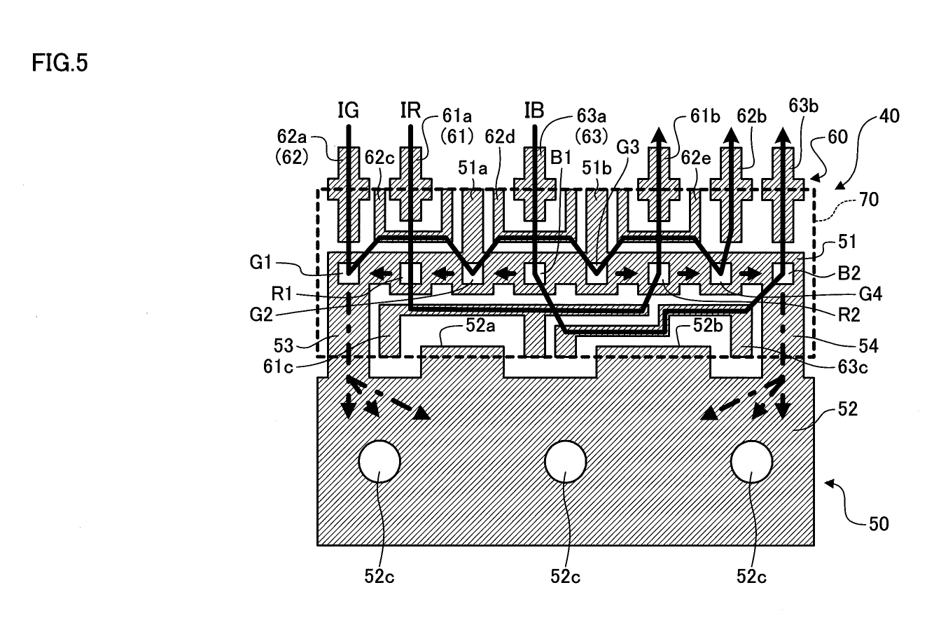

FIG. 6 is a flowchart for explaining a manufacturing process of the light emitting modules;

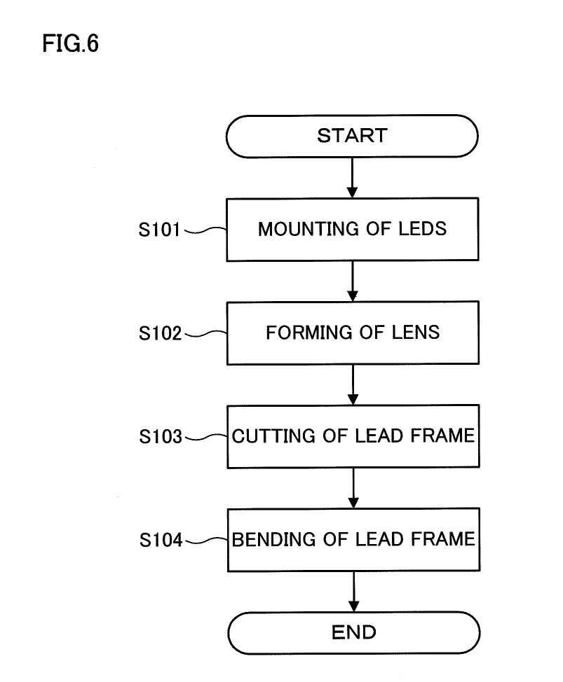

FIG. 7 is a top view of the lead frame that is an initial material of the light emitting module;

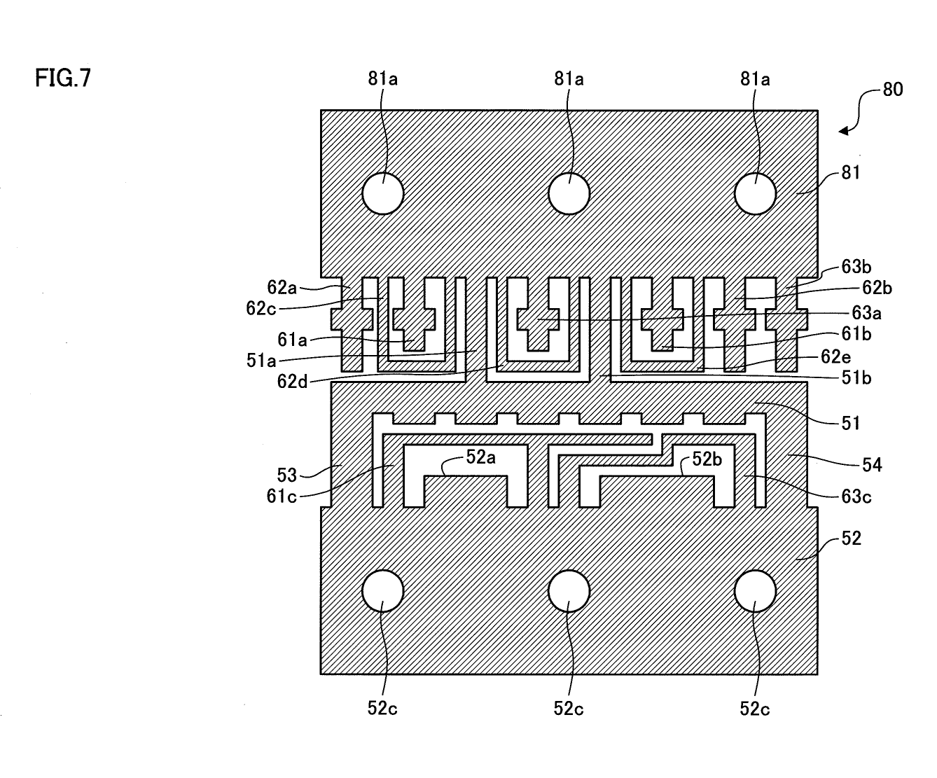

FIG. 8 is a top view of the lead frame having the LEDs mounted thereon;

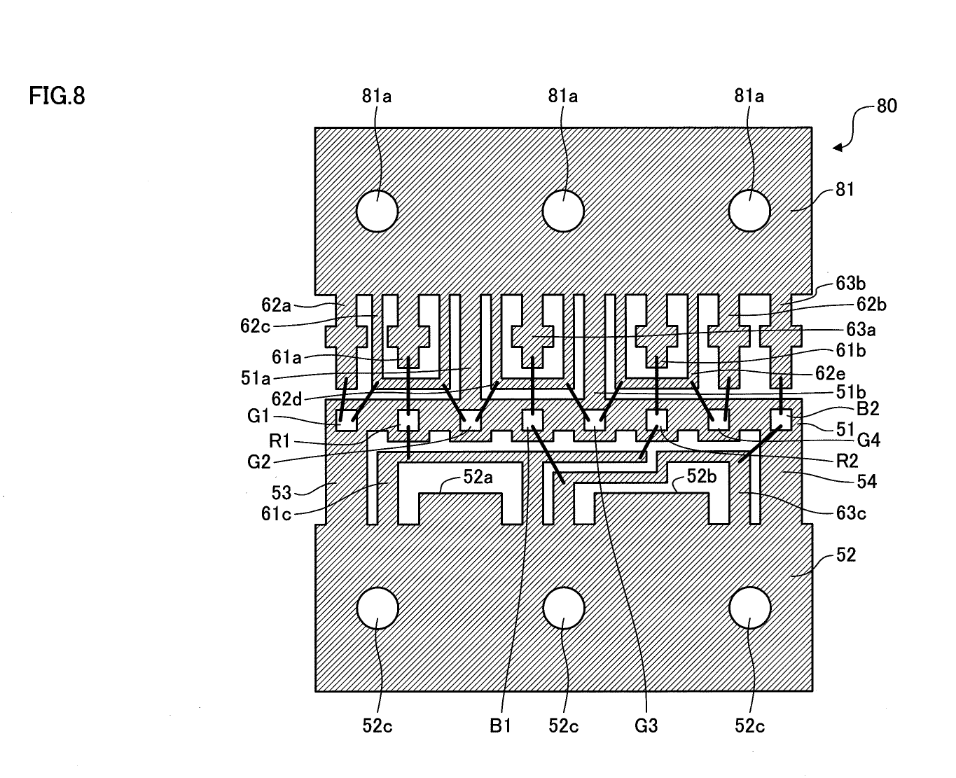

FIG. 9 is a top view of the lead frame having the lens formed thereon;

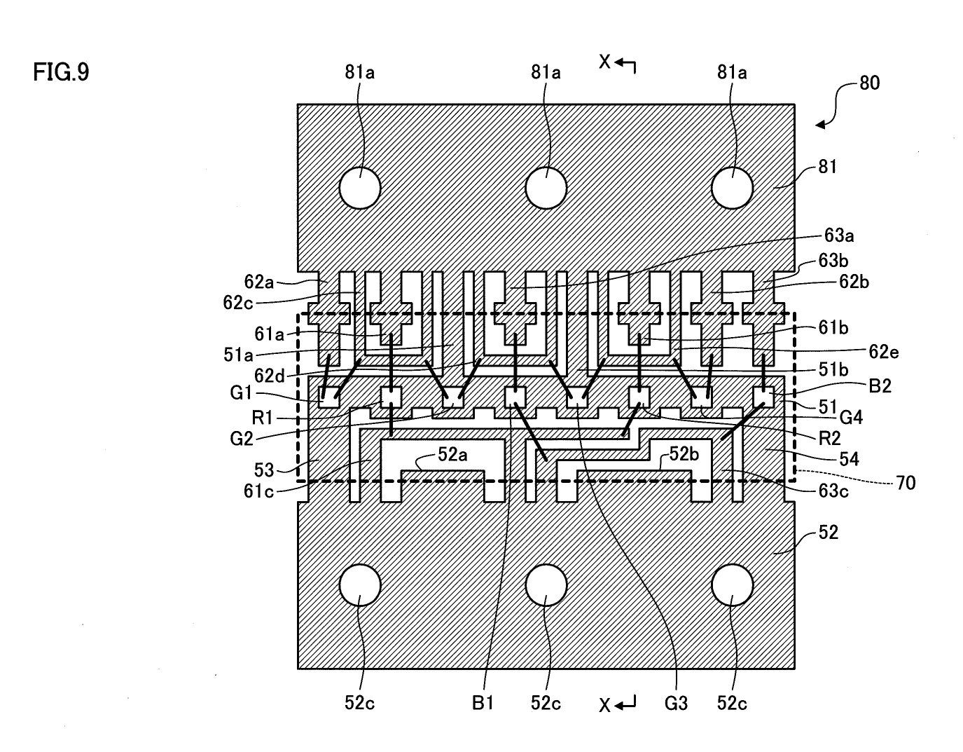

FIG. 10 is a cross sectional view of FIG. 9 taken along a line X-X;

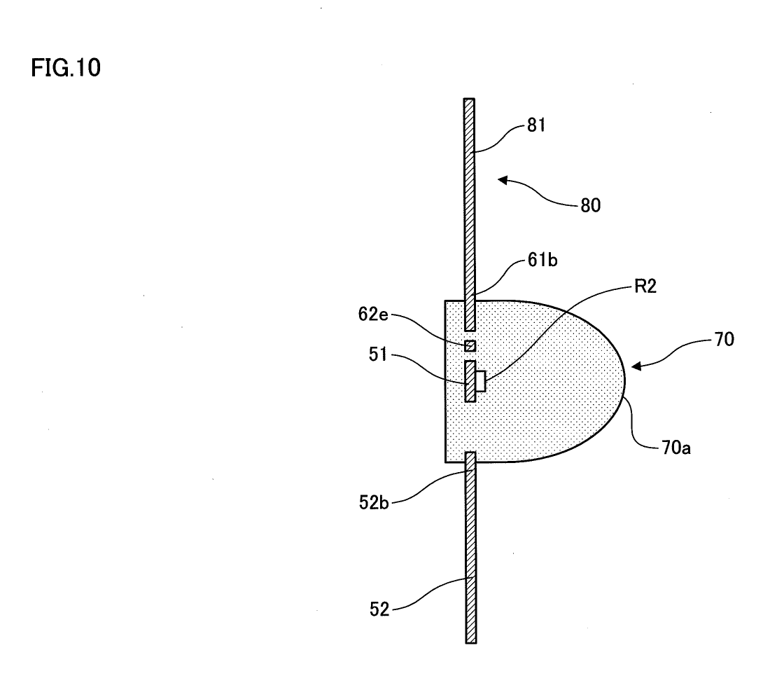

FIG. 11 is a top view of the lead frame after the specific portions are cut; and

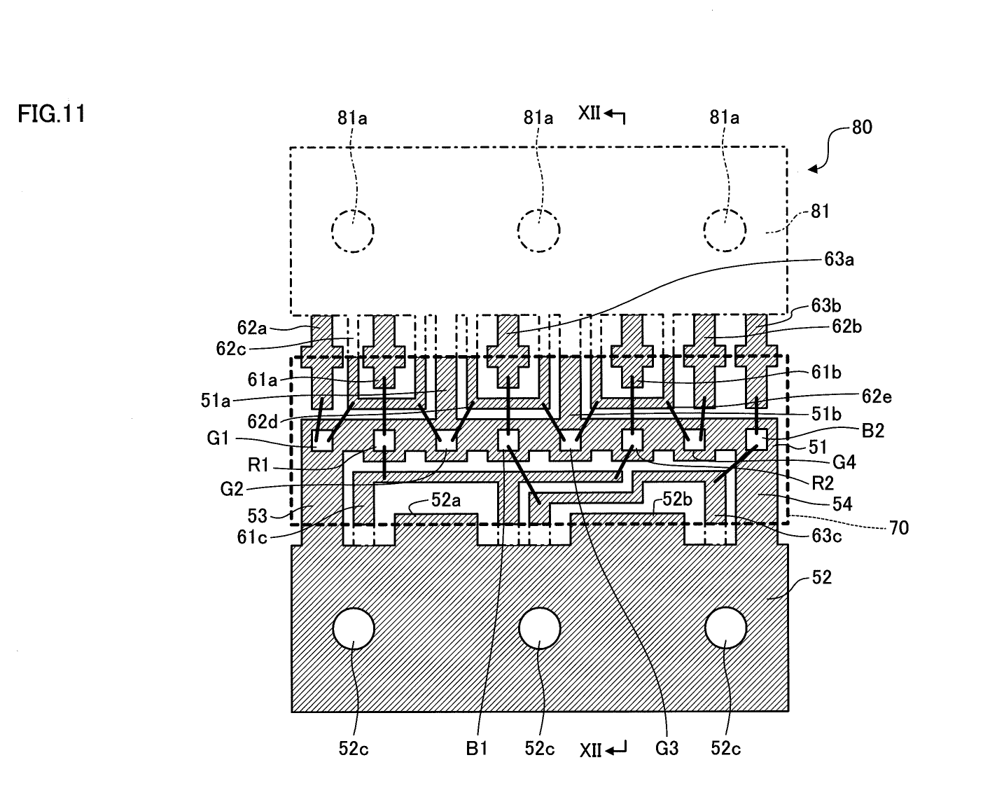

FIG. 12 is a cross-sectional view of the lead frame after being subjected to the bending processing, that is, the light emitting module.

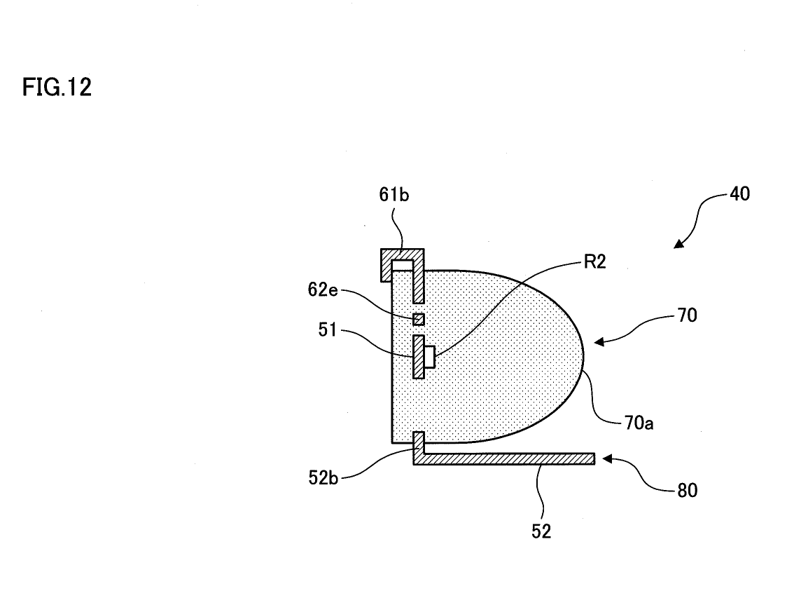

### DESCRIPTION OF REFERENCE NUMERALS AND SIGNS

10 . . . backlight device
11 . . . light source device
12 . . . light guide plate
20 . . . liquid crystal display module
31 . . . light emitting unit
32 . . . wiring board
33 . . . heat dissipating plate
40 (40a to 40j) . . . light emitting module
50 . . . heat conductor part
51 . . . holding portion
52 . . . heat dissipating portion
53 . . . first connecting portion
54 . . . second connecting portion
60 . . . electric conductor part
61 . . . red electric conductor part
62 . . . green electric conductor part
63 . . . blue electric conductor part
70 . . . lens
80 . . . lead frame
81 . . . base
R1 . . . first red LED
R2 . . . second red LED
G1 . . . first green LED
G2 . . . second green LED
G3 . . . third green LED
G4 . . . fourth green LED
B1 . . . first blue LED
B2 . . . second blue LED

1. A light emitting device comprising:
a plurality of light emitting elements;
an electric conductor that is electrically connected to each of the plurality of light emitting elements, and that forms a power feeding route for the plurality of light emitting elements;
a heat conductor that is disposed so as to be electrically insulated from the electric conductor, and that forms a heat dissipating route for heat produced by the plurality of light emitting elements; and
a sealing part that seals the plurality of light emitting elements while including a part of the electric conductor and a part of the heat conductor, wherein
respective portions, exposed from the sealing part, of the electric conductor and the heat conductor are bent.

2. The light emitting device according to claim 1, wherein
the sealing part has a passage surface through which light emitted from the plurality of light emitting elements passes, and
the heat conductor is bent toward the passage surface side of the sealing part.

3. The light emitting device according to claim 1, wherein the plurality of light emitting elements are arrayed in line.

4. The light emitting device according to claim 1, wherein
the plurality of light emitting elements includes a red light emitting element that emits red light, a green light emitting element that emits green light, and a blue light emitting element that emits blue light, and
the electric conductor has a red power feeding route for feeding electric power to the red light emitting element, a green power feeding route for feeding electric power to the green light emitting element, and a blue power feeding route for feeding electric power to the blue light emitting element.

5. The light emitting device according to claim 1, wherein
the electric conductor includes a plurality of electrodes that receive power feeding from an outside, and a connecting conductor that electrically connects each of the plurality of electrodes and the plurality of light emitting elements,
the heat conductor includes a holding part that holds the plurality of light emitting elements, and a transmission part that is connected to the holding part and that transmits heat produced by the plurality of light emitting elements through the holding part, and
respective parts of the electrodes are exposed from the sealing part in the electric conductor, and a part of the transmission part is exposed from the sealing part in the heat conductor.

6. The light emitting device according to claim 5, wherein
the plurality of electrodes forming the electric conductor are arranged side by side on one end portion side of the sealing part, and the transmission part forming the heat conductor is arranged on the other end portion side of the sealing part.

7. A display device comprising:
a display panel for displaying an image; and
a backlight that is disposed on a back side of the display panel and that illuminates, with light, the display panel from the back side thereof; wherein
the backlight includes:
a light guide plate that emits light incident on a side surface thereof toward the display panel; and
a light source that illuminates, with light, the light guide plate from the side surface thereof, wherein
the light source includes:
a plurality of light emitting elements;
an electric conductor that is electrically connected to each of the plurality of light emitting elements, and that forms a power feeding route for the plurality of light emitting elements;
a heat conductor that is disposed so as to be electrically insulated from the electric conductor, and that forms a heat dissipating route for heat produced by the plurality of light emitting elements; and
a sealing part that seals the plurality of light emitting elements while including a part of the electric conductor and a part of the heat conductor, and
respective portions, exposed from the sealing part, of the electric conductor and the heat conductor are bent.

8. The display device according to claim 7, wherein a plurality of the light sources are attached so as to be arrayed side by side along the side surface of the light guide plate.

9. The display device according to claim 8, further comprising a wiring board that is arranged so as to stride the plurality of light sources, and electrically connected to the electric conductor disposed in each of the plurality of light sources.

10. The display device according to claim 7, wherein the heat conductor is bent in a direction closer to the light guide plate, and the electric conductor is bent in a direction away from the light guide plate.

11. The display device according to claim 7, wherein the sealing part has a passage surface through which light emitted from the plurality of light emitting elements passes, the passage surface being aspheric.

12. A manufacturing method of a light emitting device including a plurality of light emitting elements, an electric conductor that is electrically connected to each of the plurality of light emitting elements and forms a power feeding route for the plurality of light emitting elements, a heat conductor that is disposed so as to be electrically insulated from the electric conductor and forms a heat dissipating route for heat produced by the plurality of light emitting elements, and a sealing part that seals the plurality of light emitting elements, the manufacturing method comprising the steps of:
mounting the plurality of light emitting elements on a lead frame in which the electric conductor and the heat conductor are connected through a bridging part;
forming the sealing part to the lead frame having the plurality of light emitting elements mounted thereon, the sealing part sealing the plurality of light emitting elements while including a part of the electric conductor and a part of the heat conductor;
removing the bridging part from the lead frame having the sealing part formed thereto; and
bending respective portions, exposed to an outside, of the electric conductor and the heat conductor.

13. The manufacturing method of the light emitting device according to claim 12, wherein
the electric conductor of the lead frame includes a plurality of electrodes that receive power feeding from an outside, and a connecting conductor that electrically connects the plurality of electrodes and the plurality of light emitting elements,
the heat conductor of the lead frame includes a holding part that holds the plurality of light emitting elements, and a transmission part that is connected to the holding part and that transmits heat produced by the plurality of light emitting elements through the holding part, and
the step of forming includes exposing respective parts of the electrodes from the sealing part, and exposing a part of the transmission part from the sealing part.

14. The manufacturing method of the light emitting device according to claim 12, wherein, in the step of forming, the sealing part is not formed to the bridging part.

15. The manufacturing method of the light emitting device according to claim 12, wherein the step of forming includes forming, to the sealing part, a passage surface through which light emitted from the plurality of light emitting elements having been sealed passes.

16. The manufacturing method of the light emitting device according to claim 15, wherein the step of bending includes bending the heat conductor toward the passage surface side of the sealing part, and bending the electric conductor toward a side opposite to the passage surface side.
